(19) United States
(12) Patent Application Publication
(10) Pub. No.: US 2026/0130144 A1
(43) Pub. Date: May 7, 2026

(54) METHODS OF SELECTIVELY ETCHING SILICON

(71) Applicant: Applied Materials, Inc., Santa Clara, CA (US)

(72) Inventors: Doreen Wei Ying Yong, Singapore (SG); Chiew Wah Yap, Singapore (SG); Mikhail Korolik, San Jose, CA (US); Paul E. Gee, San Jose, CA (US)

(73) Assignee: Applied Materials, Inc., Santa Clara, CA (US)

(21) Appl. No.: 18/937,925

(22) Filed: Nov. 5, 2024

(51) Int. Cl. H01L 21/3065; C09K 13/06; C09K 13/10

(52) U.S. Cl. CPC H10P 50/242; C09K 13/06; C09K 13/10

(57) ABSTRACT

Embodiments of the present disclosure are directed to methods of selectively etching silicon. The methods include flowing a precursor comprising one or more of an interhalogen, a halogen-containing species, a pseudohalogen species, a mixture of one or more of the interhalogen, the halogen-containing species, or the pseudohalogen species and one or more of an amine, a phosphine, a glycol, or an acid, or a mixture of one or more of the interhalogen, the halogen-containing species, the pseudohalogen species and a sulfur-containing species, into a semiconductor processing chamber containing a substrate; forming an activated species of the precursor; and exposing the substrate to the activated species to etch the substrate. The methods selectively etch silicon relative to silicon germanium, silicon oxide, and/or silicon nitride.

### TECHNICAL FIELD

Embodiments of the disclosure relate to the field of electronic device manufacturing. More particularly, embodiments of the disclosure relate to methods of selectively etching silicon.

### BACKGROUND

Integrated circuits are made possible by processes which produce intricately patterned material layers on substrate surfaces. Producing patterned material on a substrate requires controlled methods for removal of exposed material. Chemical etching processes are used for a variety of purposes, including transferring a pattern in photoresist into underlying layers, thinning layers, or thinning lateral dimensions of features already present on a surface. Chemical etching processes typically include chemistries that etch one material (e.g., a first material) faster than another (e.g., a second material) facilitating, for example, a pattern transfer process. Such an etch process is said to be selective to the first material. As a result of the diversity of materials, circuits, and processes, etch processes have been developed with a selectivity towards a variety of materials.

The fabrication of three-dimensional dynamic random access memory (3D-DRAM) devices, for example, includes the formation of alternating silicon (Si) and one or more of silicon germanium (SiGe), silicon oxide (SiO₂), or silicon nitride (Si₃N₄) layers. After the formation of a stack of alternating layers, the silicon (Si) layers are selectively etched to form recesses leaving behind the desired device structures, facilitating the creation of these intricate 3D architectures.

Etch processes may be termed “wet” or “dry” based on the materials used in the process. A wet HF etch preferentially removes silicon oxide over other dielectric materials. However, wet processes may have difficulty penetrating some constrained trenches and also may sometimes deform the remaining material. Dry etches produced in local plasmas formed within a substrate processing region can penetrate more constrained trenches and exhibit less deformation of delicate remaining structures. However, local plasmas may damage the substrate through the production of electric arcs as they discharge. There is a need for improved systems and methods that can be used to produce high quality structures and devices.

Currently, wet etching processes are typically used to selectively remove the silicon layers. However, in the drying process after the wet etching process, the suspended silicon oxide layers may collapse due to surface tension of the liquid. This leads to yield losses. Another issue with wet etching processes is that with future scaling of the vertical (V)-NAND (i.e., 3D-NAND) devices and 3D-DRAM devices, for example, the number of layers of silicon and silicon germanium increases. This is problematic because the liquid etchant will have difficulty filling into a deeper trench. This results in non-uniform etching, such that the etching of the top of the 3D-DRAM device is different than the etching of the bottom of the 3D-DRAM device. With the future scaling of devices, uniform or “conformal” etching is a manufacturing requirement.

Current dry etching techniques also etch silicon oxide, in addition to silicon, thereby reducing selectivity of such processes. Accordingly, there is a need for improved etch processes that achieve improved etching selectivity.

### SUMMARY

One or more embodiments are directed to a method comprising: flowing a precursor comprising one or more of an interhalogen, a halogen-containing species, a pseudohalogen species, a mixture of one or more of the interhalogen, the halogen-containing species, or the pseudohalogen species and one or more of an amine, a phosphine, a glycol, or an acid, or a mixture of one or more of the interhalogen, the halogen-containing species, or the pseudohalogen species and a sulfur-containing species, into a semiconductor processing chamber containing a substrate; forming an activated species of the precursor; exposing the substrate to the activated species; and etching the substrate. The substrate has a plurality of alternating layers of silicon and silicon oxide thereon. The silicon layers are selectively etched relative to the silicon oxide layers.

Additional embodiments are directed to a method comprising: flowing a precursor comprising one or more of an interhalogen, a halogen-containing species, a pseudohalogen species, a mixture of one or more of the interhalogen, the halogen-containing species, or the pseudohalogen species and one or more of an amine, a phosphine, a glycol, or an acid, or a mixture of one or more of the interhalogen, the halogen-containing species, or the pseudohalogen species and a sulfur-containing species, into a semiconductor processing chamber containing a substrate; forming an activated species of the precursor; exposing the substrate to the activated species; and etching the substrate. The substrate has a plurality of alternating layers of silicon and silicon germanium thereon. The silicon layers are selectively etched relative to the silicon germanium layers.

Further embodiments are directed to a method comprising: flowing a precursor comprising one or more of an interhalogen, a halogen-containing species, a pseudohalogen species, a mixture of one or more of the interhalogen, the halogen-containing species, or the pseudohalogen species and one or more of an amine, a phosphine, a glycol, or an acid, or a mixture of one or more of the interhalogen, the halogen-containing species, or the pseudohalogen species and a sulfur-containing species, into a semiconductor processing chamber containing a substrate; forming an activated species of the precursor; exposing the substrate to the activated species; and etching the substrate, The substrate has a plurality of alternating layers of silicon and silicon germanium thereon, and alternating silicon oxide layers and silicon nitride layers in contact with the alternating silicon layers and silicon germanium layers. The silicon layers are selectively etched relative to the silicon oxide layers and the silicon nitride layers.

### BRIEF DESCRIPTION OF THE DRAWINGS

So that the manner in which the above recited features of the disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements.

FIG. 1 illustrates a process flow diagram of a method of selectively etching silicon, in accordance with one or more embodiments;

FIG. 2A illustrates a cross-sectional schematic view of a substrate having a first material and a second material, in accordance with one or more embodiments;

FIG. 2B illustrates a cross-sectional schematic view of the substrate of FIG. 2A after exposure to a precursor, and formation of a passivation layer on the second material, in accordance with one or more embodiments;

FIG. 2C illustrates a cross-sectional schematic view of the substrate of FIG. 2B after a thermal/purge release process, in accordance with one or more embodiments;

FIG. 3A illustrates a cross-sectional schematic view of a portion of a structure having alternating silicon layers and silicon oxide layers, in accordance with one or more embodiments of the disclosure;

FIG. 3B illustrates a cross-sectional schematic view of a portion of the structure of FIG. 3A after selectively etching the silicon layers, in accordance with one or more embodiments;

FIG. 3C illustrates a cross-sectional schematic view of a portion of a structure having alternating silicon layers and silicon germanium layers and selectively etching the silicon layers relative to the silicon germanium layers, in accordance with one or more embodiments; and

FIG. 3D illustrates a cross-sectional schematic view of a portion of a structure having alternating silicon layers and silicon germanium layers, and silicon oxide layers and silicon nitride layers in contact with the alternating silicon layers and silicon germanium layers, and selectively etching the silicon layers relative to the silicon oxide layers and the silicon nitride layers, in accordance with one or more embodiments.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “about” as used herein means approximately or nearly and in the context of a numerical value or range set forth means a variation of ±15%, or less, of the numerical value. For example, a value differing by ±14%, ±10%, ±5%, ±2%, or ±1%, would satisfy the definition of about.

Spatially relative terms, such as “beneath,” “below,” “lower,” “above,” “upper” and the like, may be used herein for ease of description to describe one element's relationship to another element(s) or feature(s) as illustrated in the Figures. It will be understood that the spatially relative terms are intended to encompass different orientations of the device in use or operation in addition to the orientation depicted in the Figures. For example, if the device in the Figures is turned over, elements described as “below” or “beneath” other elements would then be oriented “above” the other elements. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein.

All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments,” “some embodiments,” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in some embodiments,” “in one embodiment,” or “in an embodiment” in various places throughout this specification are not necessarily referring to the same embodiment of the disclosure. In one or more embodiments, the particular aspects, structures, materials, or characteristics are combined in any suitable manner.

As used in this specification and the appended claims, the term “substrate” and “wafer” are used interchangeably, both referring to a surface, or portion of a surface, upon which a process acts. It will also be understood by those skilled in the art that reference to a substrate can also refer to only a portion of the substrate, unless the context clearly indicates otherwise. Additionally, reference to “depositing on” or “forming on” a substrate can mean both a bare substrate and a substrate with one or more films or features deposited or formed therein/thereon.

A “substrate” as used herein, refers to any substrate or material surface formed on a substrate upon which film processing is performed during a fabrication process. For example, a substrate surface on which processing can be performed include dielectric materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application.

In some embodiments, the substrate includes at least one conductive material and at least one dielectric material.

Substrates can include, without limitation, semiconductor substrates/semiconductor materials. In some embodiments, the semiconductor substrate comprises one or more of doped or undoped crystalline silicon (Si), doped or undoped crystalline silicon germanium (SiGe), doped or undoped amorphous silicon (Si), or doped or undoped amorphous silicon germanium (SiGe).

Substrates may be exposed to a pretreatment process to polish, etch, reduce, oxidize, hydroxylate (or otherwise generate or graft target chemical moieties to impart chemical functionality), anneal and/or bake the substrate surface. In addition to film processing directly on the surface of the substrate itself, in the disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

The substrate may have one or more features formed therein, one or more layers formed thereon, or combinations thereof. The shape of the feature can be any suitable shape including, but not limited to, trenches, holes and vias (circular or polygonal). As used in this regard, the term “feature” refers to any intentional surface irregularity. Suitable examples of features include but are not limited to trenches, which have a top, two sidewalls comprising, for example, a dielectric material, and a bottom extending into the substrate, the bottom comprising, for example, a metallic material, or vias which have one or more sidewalls extending into the substrate to a bottom.

The features described herein can extend vertically into the substrate and/or laterally within the substrate. Unless specifically indicated otherwise, the features described herein are not limited to either of a vertically extending feature or a laterally extending feature. In one or more embodiments, the substrate comprises at least one vertically extending feature. In one or more embodiments, the substrate comprises at least one laterally extending feature. In one or more embodiments, the substrate comprises at least one vertically extending feature and at least one laterally extending feature.

The features described herein can have any suitable aspect ratio (ratio of the depth of the feature to the width of the feature). In one or more embodiments, the aspect ratio of the features described herein is greater than or equal to about 1:1, 2:1, 5:1, 10:1, 15:1, 20:1, 25:1, 30:1, 35:1, 40:1, 50:1, 60:1, 70:1, 80:1, 90:1, 100:1, 125:1, or 150:1. In one or more embodiments, the aspect ratio of the features described herein is in a range of from 1:1 to 150:1.

The term “on” indicates that there is direct contact between elements. The term “directly on” indicates that there is direct contact between elements with no intervening elements.

As used herein, the term “in situ” refers to processes that are all performed in the same semiconductor processing chamber or within different semiconductor processing chambers that are connected as part of an integrated processing system, such that each of the processes are performed without an intervening vacuum break. As used herein, the term “ex situ” refers to processes that are performed in at least two different semiconductor processing chambers such that one or more of the processes are performed with an intervening vacuum break. In some embodiments, processes are performed without breaking vacuum or without exposure to ambient air.

As used herein, the terms “precursor,” “reactant,” “reactive gas,” “reactive species,” and the like are used interchangeably to refer to any gaseous species that can react with the substrate surface.

Embodiments of the disclosure advantageously provide improved chemical etching processes including a precursor comprising one or more chemistries that, when implemented in a process cycle, achieve improved etching selectivity.

Without intending to be bound by theory, it is thought that the precursor comprising one or more chemistries, when implemented in a process cycle, achieve improved uniformity and/or increased etch rate, depending on the process parameters. The skilled artisan may optimize process parameters in order to achieve improved uniformity and/or increased etch rate using the precursor comprising one or more chemistries of the disclosure.

Embodiments of the disclosure provide a precursor comprising one or more of an interhalogen, a halogen-containing species, a pseudohalogen species, a mixture of one or more of the interhalogen, the halogen-containing species, or the pseudohalogen species and one or more of an amine, a phosphine, a glycol, or an acid, or a mixture of one or more of the interhalogen, the halogen-containing species, or the pseudohalogen species and a sulfur-containing species. In some embodiments, the use of the precursor described herein constitutes a dry etching process. As such, there is no post-etch drying step that could potentially damage the resulting structures.

In one or more embodiments, the precursor can passivate a substrate and/or at the same time help to increase silicon etch by converting a surface to another silicon by-product having a relatively low boiling point.

In embodiments where the precursor comprises a mixture of one or more of the interhalogen, the halogen-containing species, or the pseudohalogen species and one or more of an amine, a phosphine, a glycol, or an acid, or a mixture of one or more of the interhalogen, the halogen-containing species, the pseudohalogen species and a sulfur-containing species, the substrate is exposed to the precursor in a cyclic fashion, such that at least one of the components of the mixture in the complements another component in the mixture to increase silicon etch.

It has been found that the amine in the precursor described herein advantageously etches silicon (Si) and passivates silicon germanium (SiGe). It has been found that the phosphine in the precursor described herein advantageously provides ligand exchange of silicon (Si) to volatile by-products, thereby increasing silicon etch. It has been found that the glycol in the precursor described herein advantageously provides ligand exchange of silicon (Si) to volatile by-products, thereby increasing silicon etch. It has been found that the acid in the precursor described herein advantageously provides ligand exchange of silicon (Si) to volatile by-products, thereby increasing silicon etch. It has been found that the sulfur-containing species in the precursor described herein advantageously passivates silicon oxide (SiO₂).

Embodiments of the disclosure provide forming an activated species of the precursor. In some embodiments, forming the activated species comprises one or more of a thermal process, generating a plasma of the precursor, or heating the substrate to a temperature of less than or equal to 500° C. using an optical radiation source.

Advantageously, the precursor comprising one or more of an interhalogen, a halogen-containing species, a pseudohalogen species, a mixture of one or more of the interhalogen, the halogen-containing species, or the pseudohalogen species and one or more of an amine, a phosphine, a glycol, or an acid, or a mixture of one or more of the interhalogen, the halogen-containing species, or the pseudohalogen species and a sulfur-containing species, when implemented in a process cycle and activated to form an activated species, achieves improved etching selectivity of silicon relative to one or more of silicon germanium, silicon oxide, or silicon nitride.

In one or more embodiments, the selective etching processes described herein are lateral etching processes.

The embodiments of the disclosure are described by way of the Figures, which illustrate selective etching processes, substrates, and devices (such as, for example, a portion of a 3D-DRAM device). The skilled artisan will recognize that the disclosed processes, substrates, and devices are not limited to the illustrated applications.

In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

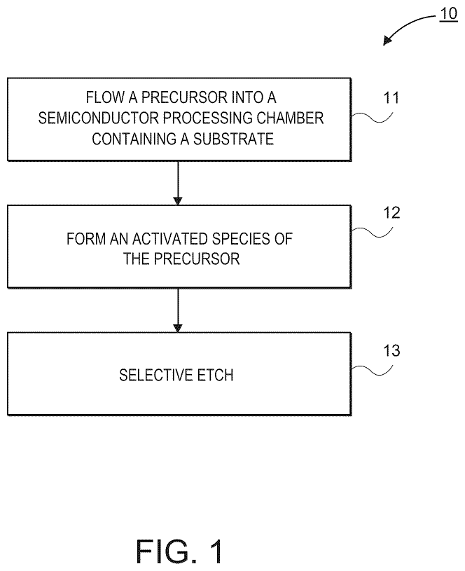

FIG. 1 illustrates a process flow diagram of a method 10 of selectively etching silicon, in accordance with one or more embodiments of the disclosure.

In some embodiments, the method 10 includes a pre-treatment operation (not shown). The pre-treatment can include any suitable pre-treatment process known to the skilled artisan. Suitable pre-treatment processes include, but are not limited to, pre-heating, cleaning, soaking, metal oxidation, or depositing a protective layer to block a surface.

In some embodiments, the method 10 is a selective etch method for a structure that is used for a 3D-DRAM device, or, more particularly, an intermediate structure used in the fabrication of a 3D-DRAM device. While one or more structures are described herein as examples, it will be appreciated by the skilled artisan that the methods described herein, e.g., the method 10, can be used with any architecture with silicon (Si) and one or more of silicon germanium (SiGe), silicon oxide (SiO₂), or silicon nitride (Si₃N₄) layers in accordance with various embodiments.

In some embodiments, the method 10 begins at operation 11, which includes flowing a precursor into a semiconductor processing chamber containing a substrate. Any suitable semiconductor processing chamber can be used. In one or more embodiments, the method 10 is performed in situ, such that all operations are performed in the same semiconductor processing chamber or within different semiconductor processing chambers that are connected as part of an integrated processing system, such that each of the processes are performed without an intervening vacuum break.

In one or more embodiments, the method 10 is performed ex situ such that one or more operations are performed in at least two different semiconductor processing chambers such that one or more of the processes are performed with an intervening vacuum break.

In some embodiments, the precursor comprises one or more of an interhalogen, a halogen-containing species, a pseudohalogen species, a mixture of one or more of the interhalogen, the halogen-containing species, or the pseudohalogen species and one or more of an amine, a phosphine, a glycol, or an acid, or a mixture of one or more of the interhalogen, the halogen-containing species, the pseudohalogen species and a sulfur-containing species.

In some embodiments, the precursor comprises, consists essentially of, or consists of an interhalogen. In some embodiments, the precursor comprises, consists essentially of, or consists of a halogen-containing species. In some embodiments, the precursor comprises, consists essentially of, or consists of a pseudohalogen species.

In some embodiments, the precursor comprises, consists essentially of, or consists of a mixture of the interhalogen and one or more of an amine, a phosphine, a glycol, or an acid. In some embodiments, the precursor comprises, consists essentially of, or consists of a mixture of halogen-containing species and one or more of an amine, a phosphine, a glycol, or an acid. In some embodiments, the precursor comprises, consists essentially of, or consists of a mixture of the pseudohalogen species and one or more of an amine, a phosphine, a glycol, or an acid.

In some embodiments, the precursor comprises, consists essentially of, or consists of a mixture of the interhalogen and the sulfur-containing species. In some embodiments, the precursor comprises, consists essentially of, or consists of a mixture of halogen-containing species and the sulfur-containing species. In some embodiments, the precursor comprises, consists essentially of, or consists of a mixture of the pseudohalogen species and the sulfur-containing species.

As used herein, the term “interhalogen” refers to a species that includes 2 or more different halogen atoms and does not include atoms or elements of any other group in the Periodic Table. The interhalogen may include any suitable interhalogen as described herein known to the skilled artisan. In some embodiments, the interhalogen comprises, consists essentially of, or consists of one or more of chlorine trifluoride (ClF₃), bromine trifluoride (BrF₃), bromine pentafluoride (BrF₅), iodine monochloride (ICI), iodine monobromide (IBr), iodine trifluoride (IF₃), iodine pentafluoride (IF₅), or iodine heptafluoride (IF₇).

In one or more embodiments, the halogen-containing species the halogen-containing species comprises, consists essentially of, or consists of one or more of fluorine (F₂), bromine (Br₂), chlorine (Cl₂), iodine (I₂), boron trichloride (BCl₃), HF-pyridine, boron tribromide (BBr₃), hydrobromic acid (HBr), trimethylchlorosilane (Me₃SiCl), dichloromethylsilane (CH₄Cl₂Si), (dielthylaminso) sulfur trifluoride (DAST), sulfur hexafluoride (SF₆), nitrogen trifluoride (NF₃), trifluoroiodomethane (CF₃I), sulfuryl chloride (SO₂Cl₂), thionyl bromide (SOBr₂), thionyl chloride (SOCl₂), xenon difluoride (XeF₂), titanium tetrachloride (TiCl₄), molybdenum pentafluoride (MoF₅), molybdenum pentachloride (MoCl₅) tungsten pentafluoride (WF₅), or tungsten pentachloride (WCl₅).

In one or more embodiments, the pseudohalogen species comprises, consists essentially of, or consists of one or more of an isocyano group, a sulfanyl group, a cyanate group, an isocyanate group, a thiocyanate group, or an isothiocyanate group. The pseudohalogen species may include any suitable compound that comprises one or more of an isocyano group, a sulfanyl group, a cyanate group, an isocyanate group, a thiocyanate group, or an isothiocyanate group. In some embodiments, the pseudohalogen species comprising one or more of an isocyano group, a sulfanyl group, a cyanate group, an isocyanate group, a thiocyanate group, or an isothiocyanate group further comprises an alkyl group, including, but not limited to an acyclic group, such as a linear alkyl group or a branched alkyl group, and a cyclic alkyl group.

In one or more specific embodiments, the pseudohalogen species comprising an isocyano group is

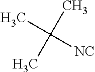

(t-butyl isocyanide). In one or more specific embodiments, the pseudohalogen species comprising a sulfanyl group is hydrogen sulfide (H₂S).

In one or more specific embodiments, the pseudohalogen species comprising an isocyanate group is

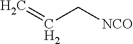

(1-propylene isocyanate).

In one or more specific embodiments, the pseudohalogen species comprising a thiocyanate group is H₃CSCN (methyl thiocyanate).

In one or more specific embodiments, the pseudohalogen species comprising an isothiocyanate group is H₃CH₂CNCS (ethyl isocyanate).

In some embodiments, the precursor flowed at operation 11 can passivate a substrate and/or at the same time help to increase silicon etch by converting a surface to another silicon by-product having a relatively low boiling point.

The amine may include any suitable compound that contains an amine group known to the skilled artisan. In one or more embodiments, the amine comprises, consists essentially of, or consists of diethylamine (DEA), tetramethylethylenediamine (TMEDA), methylamine (MEA), triethylamine (Et₃N), or ammonia (NH₃).

The phosphine may include any suitable compound that contains a phosphine group known to the skilled artisan. In one or more embodiments, the phosphine comprises, consists essentially of, or consists of triethylphosphine (PEt₃).

The glycol may include any suitable compound that contains a glycol group known to the skilled artisan. In one or more embodiments, the glycol comprises, consists essentially of, or consists of one or more of pinacol or hexylene glycol.

The acid may include any suitable compound known to the skilled artisan. In one or more embodiments, the acid comprises, consists essentially of, or consists of one or more of acetic acid or hydrochloric acid (HCl).

The sulfur-containing species may include any suitable compound that contain a sulfur species. In one or more embodiments, the sulfur-containing species comprises one or more of hydrogen sulfide (H₂S) or carbon disulfide (CS₂). In one or more embodiments, the sulfur-containing species comprises a disulfide molecule. In some embodiments, the disulfide molecule comprises one or more of Me-S—S-Me (dimethyl disulfide), Cl—S—S—Cl (disulfur dichloride), or

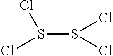

(disulfur tetrachloride).

In some embodiments, at operation 12, the method 10 includes forming an activated species (e.g., radicals) of the precursor.

Without intending to be bound by any particular theory, it is thought that the precursors (e.g., the one or more chemistries of the precursor) are aided in their effectiveness by forming an activated species of the precursor to implement the respective chemistries.

In some embodiments, forming the activated species comprises, consists essentially of, or consists of one or more of a thermal process, generating a plasma of the precursor, or heating the substrate to a temperature of less than or equal to 500° C. using an optical radiation source.

The thermal process may include any suitable process known to the skilled artisan that does not employ a plasma.

Any suitable plasma source can be used to generate a plasma of the precursor. In one or more embodiments, a remote plasma source, an inductively coupled plasma (ICP) source, a capacitively coupled plasma (CCP) source, or a microwave plasma source may be used to generate the plasma of the precursor.

The skilled artisan will appreciate that any remote plasma source, inductively coupled plasma (ICP) source, capacitively coupled plasma source (CCP) source, or microwave plasma source that is suitable for generating the plasma may be implemented for the disclosed processes.

In specific embodiments, the microwave plasma source comprises a modular microwave plasma source. Modular microwave plasma sources have a high plasma density and very low plasma potential (e.g., less than or equal to 10 eV). The high plasma density and low plasma potential results in less sputtering damage to the etched structure as compared to a typical inductively coupled plasma (ICP) source, as an example, which has a higher plasma potential (e.g., greater than or equal to about 20 eV).

While examples of specific device architectures that benefit from the use of a plasma source, such as a modular microwave source, to generate a microwave plasma of the precursor, are provided, it will be appreciated by the skilled artisan that the provided examples are non-limiting, and there may be many different applications and architectures that benefit from the precursors (e.g., the one or more chemistries of the precursor) a in accordance with one or more embodiments herein.

One or more embodiments of the present disclosure include forming the activated species by heating the substrate to a temperature of less than or equal to 500° C. using an optical radiation source. As used herein, the term “optical radiation” includes ultraviolet (UV) wavelengths, visible light wavelengths, and infrared (IR) wavelengths on the electromagnetic spectrum. In one or more embodiments, the IR radiation used has a wavelength in a range of from 780 nm to 1 mm. In one or more embodiments, the UV-visible light radiation has a wavelength in a range of from 190 nm to 900 nm.

The optical radiation may be generated by any suitable source known to the skilled artisan. In some embodiments, the optical radiation employed to form the activated species of the precursor is UV radiation, visible light radiation, or IR radiation. In some embodiments, the optical radiation employed to form the activated species of the precursor is UV radiation.

The method 10 comprises, consists essentially of, or consists of flowing the precursor (operation 11) and forming an activated species (e.g., radicals) of the precursor (operation 12) to advantageously etch silicon (operation 13, which includes operations 11 and 12) with improved etching selectivity.

While the method 10 is described as including discrete processing operations (operations 11 and 12) in order to selectively etch the substrate at operation 13, the disclosure is not limited thereto. For example, the method 10 may include any combination of the one or more chemistries of the precursor.

In some embodiments, the substrate on which the selective etch method (i.e., method 10) is performed has a plurality of alternating layers of silicon and silicon oxide thereon, and the silicon layers are selectively etched relative to the silicon oxide layers.

In some embodiments, the substrate on which the selective etch method (i.e., method 10) is performed has a plurality of alternating layers of silicon and silicon germanium thereon, and the silicon layers are selectively etched relative to the silicon germanium layers.

In some embodiments, the substrate on which the selective etch method (i.e., method 10) is performed has a plurality of alternating layers of silicon and silicon germanium thereon, and alternating silicon oxide layers and silicon nitride layers in contact with the alternating silicon layers and silicon germanium layers, and the silicon layers are selectively etched relative to the silicon oxide layers and the silicon nitride layers.

The semiconductor processing chamber can be maintained at any suitable processing conditions depending upon which precursor is used and which structure is being processed, and the processing conditions may vary.

In some embodiments, the semiconductor processing chamber is maintained at a pressure in a range of from 5 millitorr to 100 Torr, in a range of from 5 millitorr to 20 Torr, in a range of from 5 millitorr to 10 Torr, or in a range of from 5 millitorr to 5 Torr during the method 10.

It will be appreciated by the skilled artisan that the etching temperatures (i.e., substrate temperatures) for embodiments disclosed herein may be considered low temperature processes. In some embodiments, the semiconductor processing chamber is maintained at a temperature of less than or equal to 500° C., less than or equal to 400° C., less than or equal to 300° C., less than or equal to 200° C., less than or equal to 100° C., less than or equal to 50° C., less than or equal to 0° C., less than or equal to −50° C., or less than or equal to −100° C. It will be appreciated by the skilled artisan that maintaining the semiconductor chamber at a temperature of less than or equal to 100° C., such as in the range of from less than or equal to 100° C. to less than or equal to −100° C., will require the implementation of additional processing equipment, such as a cryogenic chamber.

In some embodiments, the method 10 includes flowing precursor and forming an activated species of the precursor (operations 11 and 12), for a time period in a range of from 1 second to 10 minutes. In some embodiments, the method 10 optionally includes purging the semiconductor processing chamber of the precursor and/or the activated species of the precursor.

As used herein, purging the semiconductor processing chamber removes unreacted precursors, gas mixtures, reaction products, and by-products. For example, in a sector of a spatially separated semiconductor processing chamber, the portion of the semiconductor processing chamber adjacent the substrate surface is purged of the unreacted precursor by any suitable technique including, but not limited to, moving the substrate through a gas curtain to a portion or sector of the semiconductor processing chamber that contains none or substantially none of the precursor. In one or more embodiments, purging the semiconductor processing chamber comprises applying a vacuum. In some embodiments, purging the semiconductor processing chamber comprises flowing a purge gas over the substrate. The term “adjacent” referring to the substrate surface means the physical space next to the surface of the substrate which can provide sufficient space for a surface reaction (e.g., precursor adsorption) to occur.

In one or more embodiments, the purge gas comprises one or more of argon (Ar), helium (He), krypton (Kr), neon (Ne), xenon (Xe), hydrogen (H₂), oxygen (O₂), or nitrogen (N₂). In some embodiments, purging the semiconductor processing chamber includes flowing the purge gas (e.g., helium (He)) over the substrate for a time period in a range of from 0.5 seconds to 10 minutes.

In one or more embodiments, the method 10 includes a cyclical process of flowing the precursor (operation 11), purging, forming the activated species of the precursor (operation 12), purging, then continuing with the method 10.

In some embodiments, the method 10 includes flowing one or more of the interhalogen, the halogen-containing species, or the pseudohalogen species, sequentially, or co-flowed, (operation 11), purging, forming the activated species of the precursor (operation 12), purging, then continuing with the method 10. In one or more embodiments, one or more of the interhalogen, the halogen-containing species, or the pseudohalogen species are flowed at operation 11, activated at operation 12, and used to selectively etch silicon at operation 13 without purging.

In embodiments where the precursor comprises a mixture of the interhalogen and one or more of the amine, the phosphine, the glycol, or the acid, the interhalogen and the amine, the phosphine, the glycol, and/or the acid may be flowed sequentially, or co-flowed. In embodiments where the precursor comprises a mixture of the interhalogen and one or more of the amine, the phosphine, the glycol, or the acid, the interhalogen and the amine, the phosphine, the glycol, and/or the acid may be flowed without purging. In one or more embodiments, the method 10 includes flowing the interhalogen, purging, flowing the amine, the phosphine, the glycol, and/or the acid, purging, then continuing with the method 10.

In embodiments where the precursor comprises a mixture of the interhalogen and the sulfur-containing species, the interhalogen and the sulfur-containing species may be flowed sequentially, or co-flowed. In embodiments where the precursor comprises the mixture of the interhalogen and the sulfur-containing species, the interhalogen and the sulfur-containing species may be flowed without purging. In one or more embodiments, the method 10 includes flowing the interhalogen, purging, flowing the sulfur-containing species, purging, then continuing with the method 10.

In embodiments where the precursor comprises a mixture of the halogen-containing species and one or more of the amine, the phosphine, the glycol, or the acid, the halogen-containing species and the amine, the phosphine, the glycol, and/or the acid may be flowed sequentially, or co-flowed. In embodiments where the precursor comprises a mixture of the halogen-containing species and t one or more of the amine, the phosphine, the glycol, or the acid, the halogen-containing species and the amine, the phosphine, the glycol, and/or the acid may be flowed without purging. In one or more embodiments, the method 10 includes flowing the halogen-containing species, purging, flowing the amine, the phosphine, the glycol, and/or the acid, purging, then continuing with the method 10.

In embodiments where the precursor comprises a mixture of the halogen-containing species and the sulfur-containing species, the halogen-containing species and the sulfur-containing species may be flowed sequentially, or co-flowed. In embodiments where the precursor comprises the mixture of the halogen-containing species and the sulfur-containing species, the halogen-containing species and the sulfur-containing species may be flowed without purging. In one or more embodiments, the method 10 includes flowing the halogen-containing species, purging, flowing the sulfur-containing species, purging, then continuing with the method 10.

In embodiments where the precursor comprises a mixture of the pseudohalogen species and one or more of the amine, the phosphine, the glycol, or the acid, the pseudohalogen species and the amine, the phosphine, the glycol, and/or the acid may be flowed sequentially, or co-flowed. In embodiments where the precursor comprises the mixture of the pseudohalogen species and one or more of the amine, the phosphine, the glycol, or the acid, the pseudohalogen species and the amine, the phosphine, the glycol, and/or the acid may be flowed without purging. In one or more embodiments, the method 10 includes flowing the pseudohalogen species, purging, flowing the amine, the phosphine, the glycol, and/or the acid, purging, then continuing with the method 10.

In embodiments where the precursor comprises a mixture of the pseudohalogen species and the sulfur-containing species, the pseudohalogen species and the sulfur-containing species may be flowed sequentially, or co-flowed. In embodiments where the precursor comprises the mixture of the pseudohalogen species and the sulfur-containing species, the pseudohalogen species and the sulfur-containing species may be flowed without purging. In one or more embodiments, the method 10 includes flowing the pseudohalogen species, purging, flowing the sulfur-containing species, purging, then continuing with the method 10.

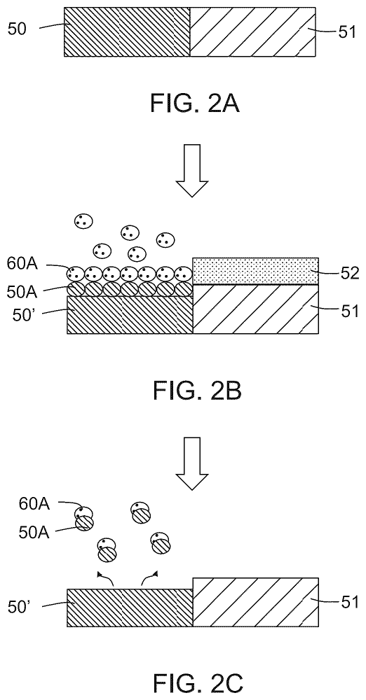

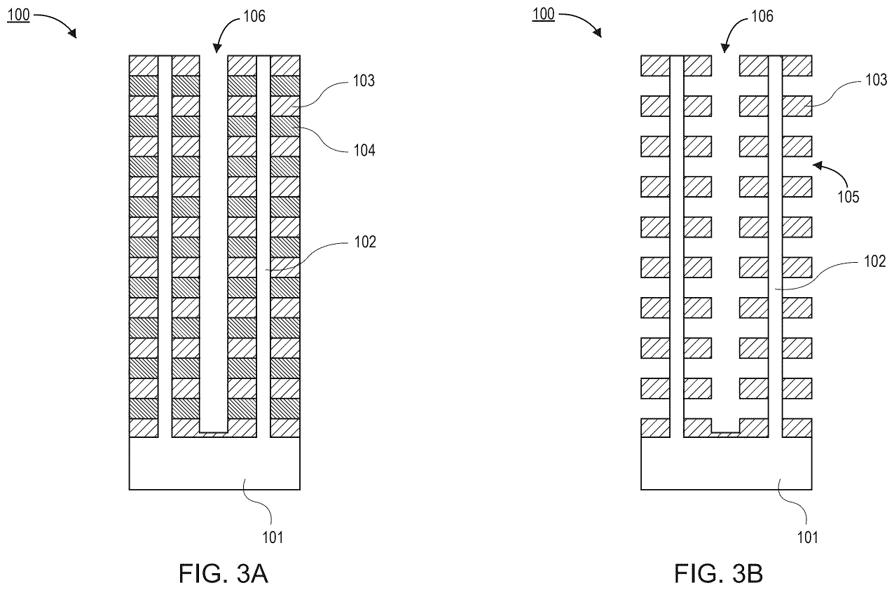

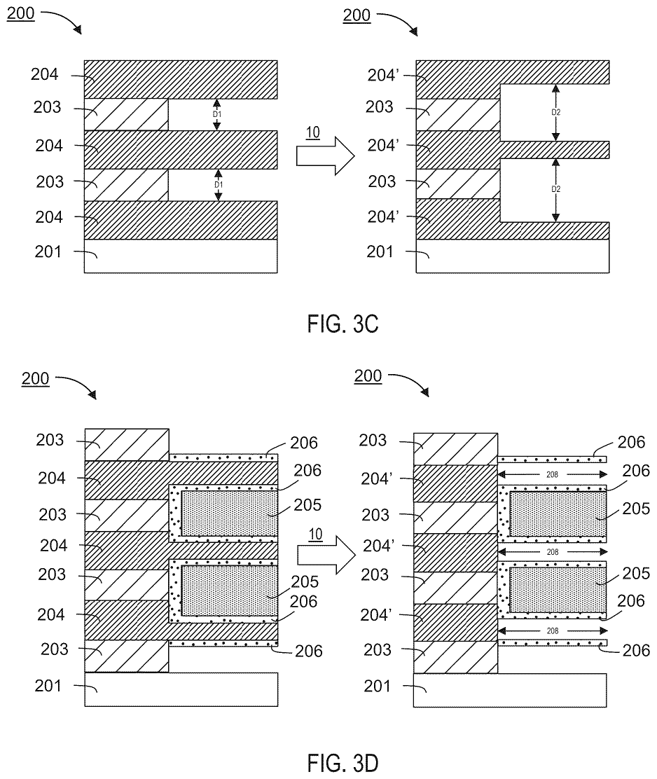

In some embodiments, at operation 13, the method 10 includes selectively etching the substrate. The operation 13 includes the processes described in operations 11 and 12, that, when implemented together in a process cycle, achieve improved etching selectivity. The improved etching selectivity achieved by the method 10 is described further herein with respect to FIGS. 2A-2C and 3A-3D.

FIGS. 2A-2C collectively illustrate a process sequence for a selective etch process, e.g., the method 10. FIG. 2A illustrates a cross-sectional schematic view of a substrate having a first material 50 and a second material 51. In one or more embodiments, the first material 50 is silicon (Si). In one or more embodiments, the second material 51 is silicon oxide (SiO₂).

FIG. 2B illustrates a cross-sectional schematic view of the substrate of FIG. 2A after exposure to a precursor, and formation of a passivation layer 52 on the second material 51.

In FIG. 2B, reference numeral 50′ refers to an etched first material, reference numeral 50A refers to etched atoms of first material, and reference numeral 60A refers to atoms of the precursor.

As discussed herein, in accordance with operation 11 of the method 10, in one or more embodiments, the precursor can passivate a substrate (i.e., to form the passivation layer 52 shown in FIG. 2B) and/or at the same time help to increase silicon etch by converting a surface to another silicon by-product having a relatively low boiling point.

Accordingly, in one or more embodiments, exposing the substrate of FIG. 2A to the precursor forms the resulting structure illustrated in FIG. 2B.

FIG. 2C illustrates a cross-sectional schematic view of the substrate of FIG. 2B after a thermal/purge release process. The thermal/purge release process includes removal of etched atoms of first material 50A and atoms of the precursor 60A (denoted by the curved arrows extending up from the first material 50). The etched first material 50′ has a thickness that is reduced compared to a thickness of the first material 50. FIGS. 2A-2C collectively illustrate a process sequence for a selective etch process, e.g., the method 10, of selectively etching the first material 50 (i.e., silicon) relative to the second material 51 (i.e., silicon oxide (SiO₂)).

FIG. 3A illustrates a cross-sectional schematic view of a portion of a structure with alternating silicon layers and silicon oxide layers. FIG. 3B illustrates a cross-sectional view of a portion of the structure of FIG. 3A after selectively etching the silicon layers in accordance with the method 10.

In one or more embodiments, the methods described herein are implemented on a 3D structure 100, shown in FIGS. 3A and 3B. For example, the 3D structure 100 may be a structure used for a 3D-NAND device. The 3D structure 100 includes a substrate 101, such as a polysilicon substrate, with polysilicon pillars 102 extending up from the substrate 101. In one or more embodiments, each polysilicon pillar 102 is lined by alternating layers of silicon oxide and silicon, i.e., silicon oxide layers 103 and silicon layers 104, respectively. The sidewalls of the silicon layers 104 and the silicon oxide layers 103 may be exposed by a trench 106 that passes through the layers between the polysilicon pillars 102.

The trench 106 can have any suitable dimensions. In one or more embodiments, the trench 106 has a depth of greater than or equal to 1 μm.

In some embodiments, the silicon layers 104 are sacrificial layers. In embodiments where the silicon layers 104 are sacrificial layers, the silicon layers 104 are etched away, as shown in FIG. 3B. The removal of the silicon layers 104 results in the formation of recesses 105 between the silicon oxide layers 103. In some embodiments, the recesses 105 are subsequently filled with a conductive material.

Advantageously, embodiments of the present disclosure precursors that provide a high etch selectivity of the silicon layers 104 relative to the silicon oxide layers 103. Embodiments of the present disclosure advantageously increase the etching rate of silicon and thereby reduce the time needed to etch the silicon layers 104. Embodiments of the present disclosure include using optical radiation or a plasma source, such as a modular microwave source, to generate an activated species of the precursor.

In FIGS. 3A and 3B, the 3D structure 100 may be used for a 3D-NAND device. The use of the selective etch methods described herein are particularly beneficial for use in 3D-NAND devices. In one or more embodiments, the etching uniformity is improved in highly scaled 3D-NAND devices, such as in structures with high aspect ratios and many silicon layers 104 and silicon oxide layers 103, is substantially uniform at the top of the structure and the bottom of the structure. Additionally, the selective etch methods of one or more embodiments are configured to completely remove the silicon layers 104 without significantly damaging the silicon oxide layers 103. In some embodiments, the precursor forms a passivation layer over the exposed portions of the silicon oxide layers 103 to protect the silicon oxide layers 103. Stated differently, in one or more embodiments, the precursor may be provided without etching the structure. In some embodiments, the precursor facilitates healing of the etched surfaces. In some embodiments, the precursor chemistry limits, prevents, or regenerates silicon oxide, which may maintain the silicon oxide layers 103 during exposure to the precursor.

In specific embodiments, the precursor forms a passivation layer over the exposed portions of the silicon oxide layers 103 to protect the silicon oxide layers 103.

In specific embodiments, the selective etch methods of one or more embodiments provide complete removal of the silicon layers 104 without damaging the silicon oxide layers 103 having the passivation layer thereon.

It has been advantageously found that forming the activated species of the precursor weakens the underlying bonds of the silicon layers 104, allowing the silicon layers 104 to be removed.

It will be appreciated by the skilled artisan that embodiments of the present disclosure are not limited to the etching of 3D-NAND devices. For example, similar etching processes may be used wherever a silicon structure needs to be etched selectively to a silicon oxide layer. For example, in one or more embodiments, a silicon layer may be provided over a silicon oxide layer, with the disclosed etching processes etching through the silicon layer and stopping on the silicon oxide layer. In such an embodiment, the silicon oxide layer may be considered an etch stop layer.

In one or more embodiments, the silicon layers 104 are etched relative to the silicon oxide layers 103 at a selectivity ratio of greater than or equal to 10:1, greater than or equal to 20:1, greater than or equal to 50:1, greater than or equal to 100:1, greater than or equal to 500:1, greater than or equal to 700:1, greater than or equal to 1000:1, greater than or equal to 1200:1, or greater than or equal to 1600:1.

FIG. 3C illustrates a cross-sectional schematic view of a portion of a structure 200 having alternating silicon layers and silicon germanium layers and selectively etching the silicon layers 204 relative to the silicon germanium layers 203. For example, the structure 200 shown in FIG. 3C may be a structure used for a 3D-DRAM device. The structure 200 shown in FIG. 3C includes a substrate 201, including the alternating silicon layers 204 and silicon germanium layers 203 thereon.

In FIG. 3C, a first distance D1 separates one respective silicon layer 204 from another silicon layer 204. The first distance D1 can be any suitable distance. In one or more embodiments, the first distance D1 is in a range of from 5 nm to 20 nm.

FIG. 3C illustrates selectively etching the silicon layers 204 relative to the silicon germanium layers 203 in accordance with the method 10. After performing the method 10, etched silicon layers 204′ are formed a second distance D2 separates one respective etched silicon layer 204′ from another etched silicon layer 204′. The method 10 etches the silicon layers 204 to form the etched silicon layers 204′. Stated differently, the method 10 reduces a thickness of a portion of the silicon layers 204 to form the etched silicon layers 204′.

The second distance D2 between one respective etched silicon layer 204′ and another etched silicon layer 204′ is greater than the first distance D1 between one respective silicon layer 204 from another silicon layer 204. In some embodiments, the second distance D2 defines a plurality of recesses that are subsequently filled with a conductive material. In one or more embodiments, the second distance D2 is in a range of from 10 nm to 50 nm.

In one or more embodiments, after performing the method 10, the etched silicon layers 204′ have a thickness of about 20 nm.

In one or more embodiments, the silicon layers 204 are etched relative to the silicon germanium layers 203 at a selectivity ratio of greater than or equal to 10:1, greater than or equal to 20:1, greater than or equal to 50:1, greater than or equal to 100:1, or greater than or equal to 500:1.

FIG. 3D illustrates a cross-sectional schematic view of a portion of a structure 200 having alternating silicon layers and silicon germanium layers, and silicon oxide layers and silicon nitride layers in contact with the alternating silicon layers and silicon germanium layers, and selectively etching the silicon layers 204 relative to the silicon oxide layers 206 and the silicon nitride layers 205.

For example, the structure 200 shown in FIG. 3D may be a structure used for a 3D-DRAM device. The structure 200 of FIG. 3D includes a substrate 201, including the alternating silicon layers 204 and silicon germanium layers 203 thereon. In one or more embodiments, the structure 200 shown in FIG. 3D includes the silicon oxide layers 206 formed directly on the silicon layers 204. In one or more embodiments, the silicon oxide layers 206 are in contact with a portion of the silicon germanium layers 203. In one or more embodiments, the silicon nitride layers 205 are not formed directly on the silicon layers 204. In one or more embodiments, the silicon nitride layers 205 are formed directly on the silicon oxide layers 206.

FIG. 3D illustrates selectively etching the silicon layers 204 relative to the silicon germanium layers 203, the silicon oxide layers 206, and the silicon nitride layers 205 to form etched silicon layers 204′ and a plurality of recesses 208. In one or more embodiments, a portion of the silicon layers 204 are etched in accordance with the method 10. In one or more embodiments, the silicon layers 204 are not completely removed in the structure 200 of FIG. 3D. In FIG. 3D, the etched silicon layers 204′ represent the remaining portion of the silicon layers 204 after the method 10. After etching the silicon layers 204 in accordance with the method 10 in FIG. 3D, some of the silicon oxide layers 206 are in contact with the silicon germanium layers 203. After etching the silicon layers 204 in accordance with the method 10 in FIG. 3D, some of the silicon oxide layers 206 are in contact with the etched silicon layers 204′. After etching the silicon layers 204 in accordance with the method 10 in FIG. 3D, some of the silicon oxide layers 206 remain in contact with the silicon nitride layers 205.

Advantageously, in FIG. 3D, the silicon layers 204 are selectively etched relative to the silicon oxide layers 206 and the silicon nitride layers 205.

The plurality of recesses 208 represent recesses that were formed as a result of the method 10. The plurality of recesses 208 can independently define any suitable shape. In one or more embodiments, each of the plurality of recesses 208 define a feature. The plurality of recesses 208 can have any suitable dimensions. In one or more embodiments, each of the plurality of recesses 208 has a depth of in a range of from 100 nm to 500 nm. In some embodiments, the plurality of recesses 208 are subsequently filled with a conductive material.

In one or more embodiments, the silicon layers 204 are etched relative to each of the silicon oxide layers 206 and the silicon nitride layers 205 at a selectivity ratio of greater than or equal to 10:1, greater than or equal to 20:1, greater than or equal to 50:1, greater than or equal to 100:1, greater than or equal to 500:1, greater than or equal to 700:1, greater than or equal to 1000:1, greater than or equal to 1200:1, or greater than or equal to 1600:1.

One or more embodiments of the disclosure are directed to a non-transitory computer readable medium including instructions, that, when executed by a controller of a processing chamber, cause the processing chamber to perform one or more of the illustrated and unillustrated operations of method 10 as described herein.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A method comprising:
flowing a precursor comprising one or more of an interhalogen, a halogen-containing species, a pseudohalogen species, a mixture of one or more of the interhalogen, the halogen-containing species, or the pseudohalogen species and one or more of an amine, a phosphine, a glycol, or an acid, or a mixture of one or more of the interhalogen, the halogen-containing species, or the pseudohalogen species and a sulfur-containing species, into a semiconductor processing chamber containing a substrate;
forming an activated species of the precursor;
exposing the substrate to the activated species; and
etching the substrate, the substrate having a plurality of alternating layers of silicon and silicon oxide thereon, wherein the silicon layers are selectively etched relative to the silicon oxide layers.

2. The method of claim 1, wherein the interhalogen comprises one or more of chlorine trifluoride (ClF₃), bromine trifluoride (BrF₃), bromine pentafluoride (BrF₅), iodine monochloride (ICI), iodine monobromide (IBr), iodine trifluoride (IF₃), iodine pentafluoride (IF₅), or iodine heptafluoride (IF₇).

3. The method of claim 1, wherein the halogen-containing species comprises one or more of fluorine (F₂), bromine (Br₂), chlorine (Cl₂), iodine (I₂), boron trichloride (BCl₃), HF-pyridine, boron tribromide (BBr₃), hydrobromic acid (HBr), trimethylchlorosilane (Me₃SiCl), dichloromethylsilane (CH₄Cl₂Si), (dielthylaminso) sulfur trifluoride (DAST), sulfur hexafluoride (SF₆), nitrogen trifluoride (NF₃), trifluoroiodomethane (CF₃l), sulfuryl chloride (SO₂Cl₂), thionyl bromide (SOBr₂), thionyl chloride (SOCl₂), xenon difluoride (XeF₂), titanium tetrachloride (TiCl₄), molybdenum pentafluoride (MoF₅), molybdenum pentachloride (MoCl₅) tungsten pentafluoride (WF₅), or tungsten pentachloride (WCl₅).

4. The method of claim 1, wherein the sulfur-containing species comprises a disulfide molecule.

5. The method of claim 4, wherein the disulfide molecule comprises one or more of Me-S—S-Me (dimethyl dilsulfide), Cl—S—S—Cl (disulfur dichloride), or 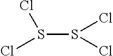
(disulfur tetrachloride).

6. The method of claim 1, wherein the pseudohalogen species comprises one or more of an isocyano group, a sulfanyl group, a cyanate group, an isocyanate group, a thiocyanate group, or an isothiocyanate group.

7. The method of claim 1, wherein the amine comprises diethylamine (DEA), tetramethylethylenediamine (TMEDA), methylamine (MEA), triethylamine (Et₃N), or ammonia (NH₃).

8. The method of claim 1, wherein the phosphine comprises triethylphosphine (PEt₃).

9. The method of claim 1, wherein the glycol comprises one or more of pinacol or hexylene glycol.

10. The method of claim 1, wherein the acid comprises one or more of acetic acid or hydrochloric acid (HCl).

11. The method of claim 1, wherein forming the activated species comprises one or more of a thermal process, generating a plasma of the precursor, or heating the substrate to a temperature of less than or equal to 500° C. using an optical radiation source.

12. The method of claim 11, wherein the plasma is generated by one or more of a microwave plasma source, a remote plasma source, an inductively coupled plasma (ICP) source, or a capacitively coupled plasma (CCP) source.

13. The method of claim 11, wherein the activated species is generated by UV radiation.

14. The method of claim 1, wherein the silicon layers are etched relative to the silicon oxide layers at a selectivity ratio of greater than or equal to 50:1.

15. The method of claim 1, wherein the substrate comprises a trench having a depth of greater than or equal to 1 μm.

16. The method of claim 1, wherein the semiconductor processing chamber is maintained at a pressure in a range of from 5 millitorr to 100 Torr and a temperature of less than or equal to 500° C.

17. The method of claim 1, further comprising purging the semiconductor processing chamber with a purge gas.

18. The method of claim 17, wherein the purge gas includes one or more of argon (Ar), helium (He), krypton (Kr), neon (Ne), xenon (Xe), hydrogen (H₂), oxygen (O₂), or nitrogen (N₂).

19. A method comprising:
flowing a precursor comprising one or more of an interhalogen, a halogen-containing species, a pseudohalogen species, a mixture of one or more of the interhalogen, the halogen-containing species, or the pseudohalogen species and one or more of an amine, a phosphine, a glycol, or an acid, or a mixture of one or more of the interhalogen, the halogen-containing species, or the pseudohalogen species and a sulfur-containing species, into a semiconductor processing chamber containing a substrate;
forming an activated species of the precursor;
exposing the substrate to the activated species; and
etching the substrate, the substrate having a plurality of alternating layers of silicon and silicon germanium thereon, wherein the silicon layers are selectively etched relative to the silicon germanium layers.

20. A method comprising:
flowing a precursor comprising one or more of an interhalogen, a halogen-containing species, a pseudohalogen species, a mixture of one or more of the interhalogen, the halogen-containing species, or the pseudohalogen species and one or more of an amine, a phosphine, a glycol, or an acid, or a mixture of one or more of the interhalogen, the halogen-containing species, or the pseudohalogen species and a sulfur-containing species, into a semiconductor processing chamber containing a substrate;
forming an activated species of the precursor;
exposing the substrate to the activated species; and
etching the substrate, the substrate having a plurality of alternating layers of silicon and silicon germanium thereon, and alternating silicon oxide layers and silicon nitride layers in contact with the alternating silicon layers and silicon germanium layers, wherein the silicon layers are selectively etched relative to the silicon oxide layers and the silicon nitride layers.
